(19) United States
(12) Patent Application Publication
(10) Pub. No.: US 2006/0125997 A1
(43) Pub. Date: Jun. 15, 2006

(54) Color filter substrate and method for manufacturing the same

(76) Inventors: Beo-Deul Kang, Seoul (KR); Yoon-Ho Kang, Yongin-si (KR)

Correspondence Address: CANTOR COLBURN, LLP, 55 GRIFFIN ROAD SOUTH, BLOOMFIELD, CT, 06002, US

(21) Appl. No.: 11/254,607

(22) Filed: Oct. 20, 2005

(30) Foreign Application Priority Data
Dec. 13, 2004 (KR) 2004-104971

(51) Int. Cl. G02F 1/1339; G03F 1/00

(52) U.S. Cl. 349/155; 430/7

(57) ABSTRACT

In a color filter substrate and a method for manufacturing the color filter substrate, the color filter substrate includes a base substrate, align portions and a color filter portion. The base substrate includes a display area and a peripheral area that is positioned around the display area. The display area has pixel areas. The align portions are formed on the peripheral area. Each of the align portions corresponds to at least one pixel area. The align portion provides an information used for arranging a nozzle of an ink-jetting device such that the nozzle jets a colored ink toward a center of each pixel area. The color filter portion is formed by jetting the colored inks to the pixel areas.

This application claims priority under 35 USC § 119 to Korean Patent Application No. 2004-104971 filed on Dec. 13, 2004 and all the benefits accruing therefrom under 35 U.S.C. 119, and, the disclosure of which is herein incorporated by reference in its entirety.

### BACKGROUND OF THE INVENTION

1. Field of the Invention

The present invention relates to a color filter substrate and a method for manufacturing the color filter substrate. In particular, the present invention relates to a color filter substrate capable of suppressing a jetting failure generated during an ink-jet printing process and a method for manufacturing the color filter substrate.

2. Description of the Related Art

In general, a liquid crystal display device includes a first substrate having a first electrode and a second substrate having a second electrode. A liquid crystal panel is formed between the first substrate and the second substrate. A voltage applied to the first electrode and the second electrode may rearrange liquid crystal molecules included in the liquid crystal panel so that the liquid crystal display device displays images. The first substrate has thin film transistors (TFTs). The second substrate may be a color filter substrate having color filter patterns.

A photolithography process or an ink-jet print process is widely used for forming a color filter pattern. In the photolithography process, a color photoresist layer is patterned to form the color filter pattern. In the ink-jet process, a colored ink is jetted to form the color filter pattern. The ink-jet print process is inexpensive and is capable of reducing costs due to its simplicity. Recently, liquid crystal display devices have increased in size. This increase in size has brought about an increase in demand for liquid crystal devices and as a result, the ink-jet process is widely used.

However, in the event that there is an alignment error between the color filter substrate and the ink-jet device, colored inks that are jetted to the color filter substrate to form the color filter patterns may be unfortunately mixed on the color filter substrate. In addition, in case that the ink-jet device has a clogged nozzle, the clogged nozzle may not jet a colored ink to form the colored filter pattern.

### SUMMARY OF THE INVENTION

The present invention provides a color filter substrate capable of suppressing an ink-jet failure generating during an ink-jet print process.

The present invention also provides a method for manufacturing the above color filter substrate.

In accordance with one aspect of the present invention, a color filter substrate comprises a base substrate, align portions and a color filter portion. The base substrate comprises a display area and a peripheral area that is disposed around the display area. The display area has pixel areas. The align portions are formed on the peripheral area. Each of the align portions corresponds to at least one pixel area. Each align portion provides information for arranging a nozzle of an ink-jetting device such that the nozzle jets a colored ink toward a center of each pixel area. The color filter portion is formed on the base substrate by jetting the colored ink to the pixel areas.

In accordance with some example embodiments of the present invention, the color filter substrate further comprises a first light-blocking pattern disposed between the pixel areas to define the respective pixel areas and further comprises a second light-blocking pattern disposed between the align portions and the color filter portion.

In accordance with some example embodiments of the present invention, the align portion and the first light-blocking pattern are formed by patterning a light-blocking layer disposed on the base substrate.

In accordance with some example embodiments of the present invention, the align portions comprise a protrusion.

In accordance with some example embodiments of the present invention, the align portions comprise a recess.

In accordance with some example embodiments of the present invention, the align portions include a first align key having a central portion with graduations arranged in a selected direction away from the central portion. The central portion is positioned on a n imaginary line passing through the centers of the corresponding pixel areas. The first align key provides a first piece of information, a second piece of information and a third piece of information. The first piece of information concerns whether or not the colored ink is jetted from the nozzle of the ink-jet device to a pixel area. The second piece of information concerns how far a center of a colored ink drop jetted from the nozzle of the ink-jet device to the pixel area is separated from a center of the pixel area. The third information concerns what direction the center of the colored ink drop jetted from the nozzle of the ink-jet device to the pixel area is separated from the center of the pixel area.

In accordance with some example embodiments of the present invention, each pixel area comprises a long side and a short side, wherein the short side is substantially shorter than the long side. The first align key includes first set of graduations and second set of graduations. The first set of graduations divide the long side into at least six equal parts. The second set of graduations divide the short side into at least two equal parts.

In accordance with some example embodiments of the present invention, the first and second set of graduations have a width substantially identical to an interval between adjacent two pixel areas.

In accordance with some example embodiments of the present invention, the align portions comprise a second align key providing a fourth piece of information concerning a position of the pixel area.

In accordance with some example embodiments of the present invention, the first align key is formed between the display area and the second align key.

In accordance with another aspect of the present invention, a color filter substrate includes a base substrate, a first align key, a second align key and a color filter portion. The color filter portion comprises red filter pattern transmitting a ray of red light, a green filter pattern transmitting a ray of green light, a blue filter pattern transmitting a ray of blue light. The base substrate includes a display area, a first peripheral area and a second peripheral area. The display area has pixel areas. The first peripheral area and the second peripheral area enclose the display area. The first align key is formed on the first peripheral area. The first align key has a central portion with graduations emanating from the central portion. The graduations are arranged in a selected direction away from the central portion. The central portion is positioned on an imaginary line passing through centers of the pixel areas. The first align key provides a first piece of information, a second piece of information and a third piece of information. The first piece of information concerns whether colored ink is jetted from a nozzle of an ink-jet device to a pixel area. The second piece of information concerns how far the center of a colored ink drop jetted from the nozzle of the ink-jet device to the pixel area is separated from the center of the pixel area. The third piece of information concerns what direction the center of the colored ink drop jetted from the nozzle of the ink-jet device to the pixel area is separated from the center of the pixel area. The second align key is formed on the second peripheral area. The second align key provides a fourth piece of information concerning a position of the pixel area. The color filter portion formed on the base substrate by jetting the colored ink to the pixel areas.

In accordance with some example embodiments of the present invention, the first align key is formed between the colored filter portion and the second align key.

In accordance with some example embodiments of the present invention, the color filter substrate further comprises a light blocking pattern defining respective pixel areas, and the first and second align keys include a material substantially identical to that included in the light-blocking pattern.

In accordance with still another aspect of the present invention, there is provided a method for manufacturing a color filter substrate as follows. A light-blocking layer is formed on a base substrate comprising a display area and a peripheral area, wherein the peripheral area is positioned around the display area. The display area has a long side and a short side, wherein the long side is substantially longer than the short side. The light-blocking layer is patterned to form a light-blocking pattern and align portions. The light-blocking pattern defines pixel areas on the display area. The align portions provide an information used for arranging a nozzle of an ink-jetting device such that the nozzle jets a colored ink toward a center of each pixel area. The align portions include first align portions and second align portions. The first align portions are arranged in a first direction substantially parallel with the long side of the display area. The second align portions are arranged in a second direction substantially parallel with the short side of the display area.

In accordance with some example embodiments of the present invention, the method further includes arranging the nozzle such that the nozzle jets the colored ink toward a center of a selected pixel area based on the information.

In accordance with some example embodiments of the present invention, arranging the nozzle comprises arranging first nozzles arranged in the first direction by using the first align portions.

In accordance with some example embodiments of the present invention, arranging the nozzle comprises arranging second nozzles arranged in the second direction by using the second align portions.

In accordance with some example embodiments of the present invention, the method further comprises forming a color filter pattern by jetting the colored inks to the pixel areas.

In accordance with some example embodiments of the present invention, the align portions include a first align key having a central portion and graduations arranged in a selected direction away from the central portion. The central portion is positioned on an imaginary line passing through the centers of corresponding pixel areas. The first align key provides a first piece of information, a second piece of information and a third piece of information. The first piece of information concerns whether or not the colored ink is jetted from the nozzle of the ink-jet device to a pixel area. The second piece of information concerns how far a center of a colored ink drop jetted from the nozzle of the ink-jet device to the pixel area is separated from a center of the pixel area. The third piece of information concerns what direction the center of the colored ink drop jetted from the nozzle of the ink-jet device to the pixel area is separated from the center of the pixel area.

In accordance with some example embodiments of the present invention, the align portions include a second align key providing a fourth piece of information concerning a position of the pixel area. Forming the align portions comprises forming the first align key between the display area and the second align key.

According to the present invention, a base substrate comprises a display area and a peripheral area that encloses the display area. A light-blocking layer formed on the base substrate is patterned to form a first align key and a second align key on the peripheral area. The first align key provides an ink-jet device with an information concerning a jetting fail. The second align key provides the ink-jet device with an information concerning a position of a pixel area where the jetting fail is generated. Thus, the ink-jet device may rearrange the base substrate and the ink-jet device so that the jetting fail may be efficiently suppressed.

### BRIEF DESCRIPTION OF THE DRAWINGS

The above and other advantages of the present invention will become readily apparent by reference to the following detailed description when considered in conjunction with the accompanying drawings wherein:

FIG. 1 is a partial perspective view illustrating an example embodiment of a color filter substrate used for a display panel;

FIG. 2 is a partial plan view illustrating an example embodiment of a method for manufacturing the color filter substrate in FIG. 1;

FIG. 3 is an enlarged view illustrating the first align key in FIG. 2;

FIG. 4 is an enlarged view illustrating an example embodiment of a first align key in accordance with the present invention;

FIG. 5 is an enlarged view illustrating an example embodiment of a first align key in accordance with the present invention; and

FIGS. 6 to 8 are plan views illustrating various types of the jetting failures detected by the color filter substrate of FIG. 1.

### DETAILED DESCRIPTION OF THE INVENTION

The invention is described more fully hereinafter with reference to the accompanying drawings, in which embodiments of the invention are shown. This invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on” or “connected to” another element or layer, it can be directly on or directly connected to the other element or layer, or intervening elements or layers may also be present.

Like reference numerals refer to like elements throughout.

It will be understood that, although the terms first, second, etc. may be used herein to describe various elements, components or layers, these elements, components or layers should not be limited by these terms. These terms are only used to distinguish one element, component or layer from another element, component or layer. Thus, a first element, component or layer discussed below could be termed a second element, component or layer without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For Example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, elements or components, but do not preclude the presence or addition of one or more other features, elements or components.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Various embodiments of the present invention will now be described with reference to the accompanying drawings.

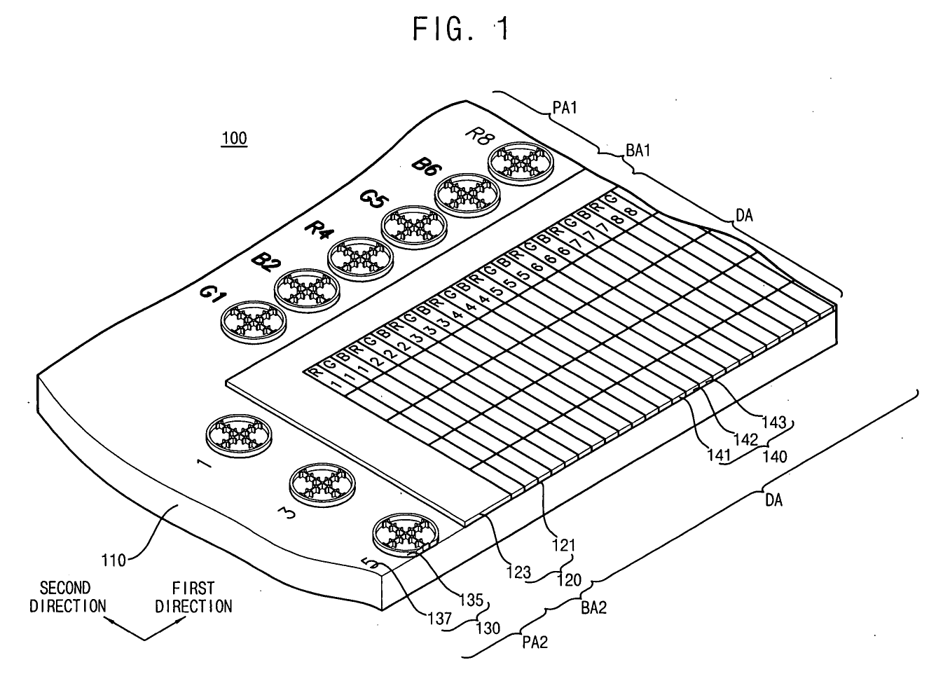

FIG. 1 is a partial perspective view illustrating one example embodiment of a color filter substrate used for a display panel.

Referring to FIG. 1, a color filter substrate 100 includes a base substrate 110, a light-blocking portion 120 and a color filter portion 140. The light-blocking portion 120 and the color filter portion 140 are positioned on the base substrate 110.

The base substrate 110 includes a display area DA, a light-blocking area BA1 and BA2 and a peripheral area PA1 and PA2. The display area DA has a long side extended in a first direction and a short side extended in a second direction. The second direction is substantially perpendicular to the first direction. The long side of the display area DA is substantially longer than the short side of the display area DA.

The light-blocking portion 120 includes a first light-blocking pattern 121 and a second light-blocking pattern 123. The first light-blocking pattern 121 is formed on the display area DA to divide the display area DA into pixel areas.

The light-blocking area BA includes a first light-blocking area BA1 extended in the first direction and a second light-blocking area BA2 extended in the second direction. The second light-blocking pattern 123 is formed on the light-blocking area BA1 and BA2 to block light that is incident on the light blocking area BA1 and BA2.

Color filter patterns are formed in the pixel areas by using an ink-jet device. The color filter patterns may be a red filter pattern 141, a green filter pattern 142, a blue filter pattern 143 or a combination thereof. A color filter portion 140 includes the red filter pattern 141, the green filter pattern 142 and the blue filter pattern 143. In one embodiment, the color filter patterns arranged in the second direction may have the same color patterns respectively as those arranged in the first direction. On the other hand, the red filter pattern 141, the green filter pattern 142 and the blue filter pattern 143 may be repeatedly arranged in the first direction as shown in the FIG. 1.

A ray of red light incident on the red filter pattern 141 may selectively pass through the red filter pattern 141. A ray of green light incident on the green filter pattern 142 may selectively pass through the green filter pattern 142. A ray of blue light incident on the blue filter pattern 143 may selectively pass through the blue filter pattern 143.

The peripheral area includes a first peripheral area PA1 adjacent to the first light-blocking area BA1 and a second peripheral area PA2 adjacent to the second light-blocking area BA2.

An align portion 130 is formed on the peripheral area PA1 and PA2. The align portion 130 includes a first align key 135 and a second align key 137. The align portion 130 and the light-blocking portion 120 may be formed by patterning a light-blocking layer (not shown).

As illustrated in FIG. 1, the light-blocking portion 120 maybe formed to be protruded with respect to the base substrate 110. In alternative embodiments, the light-blocking portion may be formed as a recess in the base substrate 110.

The first align key 135 corresponds to at least one pixel area. The first align key 135 may provide the ink-jet device with a first piece of information, a second piece of information and/or a third piece of information. The first piece of information relates to whether or not colored ink is jetted from a nozzle of the ink-jet device to the pixel area. The second piece of information relates to how far a center of a drop of the colored ink jetted from the nozzle of the ink-jet device to the pixel area is apart from a center of the pixel area. The third piece of information relates to what direction the center of the drop of the colored ink jetted from the nozzle of the ink-jet device to the pixel area is apart from the center of the pixel area.

A jetting failure is defined as one wherein the colored ink is not jetted from a nozzle of the ink-jet device to the pixel area or when the center of the drop of the colored ink jetted from the nozzle of the ink-jet device to the pixel is away from the desired center of the pixel area. When the colored ink is not jetted from a nozzle of the ink-jet device to the pixel area it is because the ink-jet device is clogged. The first align key 135 has graduations that enable the jetting failures to be represented in numbers.

The second align key 137 corresponds to the first align key 135. The second align key 137 provides the ink-jet device with a fourth piece of information. The fourth piece of information relates to the location of the pixel area in which the jetting failure is generated. The second align key 137 may be utilized as a discrimination code. In addition, the fourth piece of information may enable the ink-jet device to allocate the position of the nozzle of the ink-jet device corresponding to the pixel area in which the jetting failure is generated.

The ink-jet device calculates the distance apart and the direction that the nozzle is separated from the center of the pixel area. In one embodiment, the distance apart and the direction are calculated as numerical values based on the first, the second and the third pieces of information.

The ink-jet device then checks the location of the pixel area where the jetting failure is generated based on the fourth piece of information.

The ink-jet device may then rearrange the nozzle to correspond to the center of the pixel area based on the numerical values. Thus, the nozzle of the ink-jet device may precisely jet the colored ink toward the center of the pixel area so that the color filter pattern 140 works efficiently without the jetting failure.

In the event that the nozzles of the ink-jet device are arranged to be in the first direction, the first and second align keys 135 and 137 that are present on the first peripheral area PA1 are used for detecting an alignment error between the ink-jet device and the base substrate 110.

On the other hand, in the event that the nozzles of the ink-jet device are arranged to be in the second direction, the first and second align keys 135 and 137 that are formed on the second peripheral area PA2 are used for detecting an alignment error between the ink-jet device and the base substrate 110.

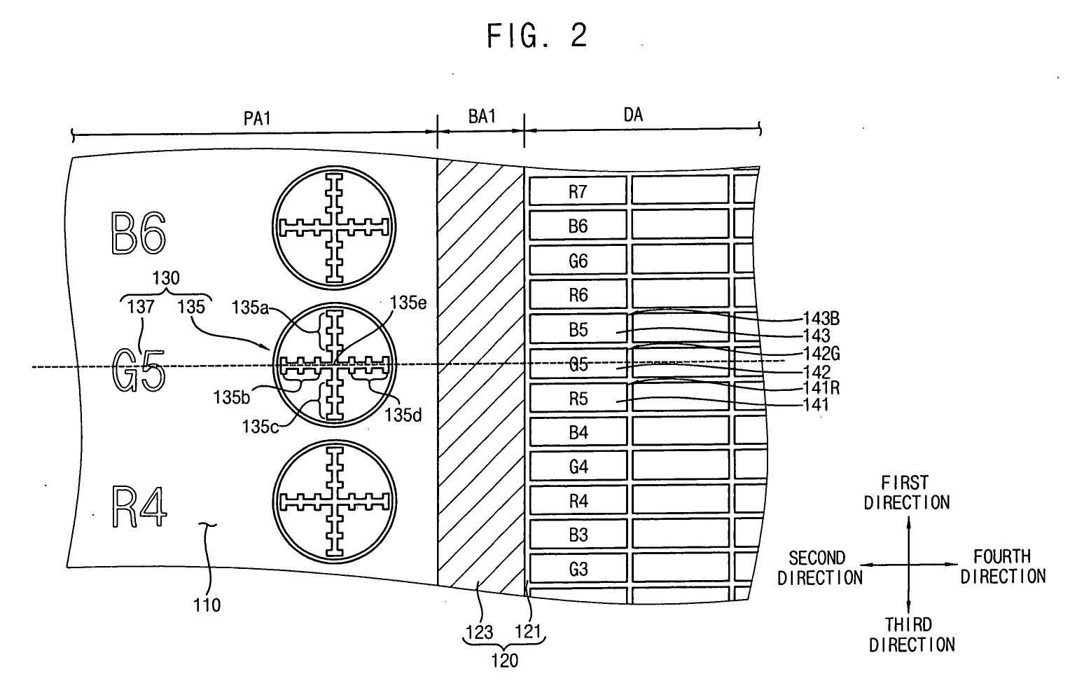

FIG. 2 is a partial plan view illustrating an example embodiment of a method for manufacturing the color filter substrate in FIG. 1.

Referring to FIG. 2, the light-blocking layer (not shown) is formed on the base substrate 110. The light-blocking layer is then patterned to form the light-blocking portion 120 and the align portion 130. The light-blocking portion 120 includes the first light-blocking pattern 121 formed on the display area DA and the second light-locking pattern 123 formed on the first light-blocking area BA1. The align portion 130 includes the first align key 135 and the second align key 137. The first align key 135 and the second align key 137 are formed on the first peripheral area PA1.

The first light-blocking pattern 121 divides the display area DA into the pixel areas. The pixel areas include a red pixel area 141R, a green pixel area 142G and a blue pixel area 143B that are adjacent to each other in the first direction. The red filter pattern 141, the green filter pattern 142 and the blue filter pixel 143 are formed in the red pixel area 141R, the green pixel area 142G and the blue pixel area 143B, respectively. The red pixel area 141R, the green pixel area 142G and the blue pixel area 143B are repeatedly arranged in the first direction.

The second light-blocking pattern 123 is formed on the first light-blocking area BA1 adjacent to the long side of the display area DA. The first align key 135 is adjacent to the first light-blocking area BA1 in the second direction. The second align key 137 is adjacent to the first align key 135 in the second direction.

The first align key 135 has a first set of graduations 135a, a second set of graduations 135b, a third set of graduations 135c, a fourth set of graduations 135d and the central portion 135e.

The first set of graduations 135a are arranged in the first direction at uniform intervals. The second set of graduations 135b are arranged in the second direction at the uniform intervals. The third set of graduations 135c are arranged in a third direction at the uniform intervals. The fourth set of graduations 135d are arranged in a fourth direction at the uniform intervals. The central portion 135e is positioned at a center of the first align key 135. The central portion 135e may be used as the first graduation for the first set of graduations 135a, the second set of graduations 135b, the third set of graduations 135c or the fourth set of graduations 135d respectively.

The central portion 135e of the first align key 135 is positioned on an imaginary line passing through the center of the pixel areas in the second direction. As illustrated in FIG. 2, in case that the first align key 135 corresponds to the red pixel area 141R, the green pixel area 142G and the blue pixel area 143B that are adjacent to each other in the first direction, the central portion 135e of the first align key 135 may correspond to a center of the green pixel area 142G. Thus, the first to fourth set of graduations 135a to 135d of the first align key 135 may enable the jetting failure to be described in numbers (i.e., numerically).

The first align key 135 may thus provide the ink-jet device with the first, the second and/or the third piece of information. As noted above, the first piece of information relates to whether or not the colored ink is jetted from the nozzle of the ink-jet device to the pixel area. The second piece of information relates to how far the center of the drop of the colored ink jetted from the nozzle of the ink-jet device to the pixel area is separated from the center of the pixel area. The third piece of information relates to what direction the center of the drop of the colored ink jetted from the nozzle of the ink-jet device to the pixel area is separated from the center of the pixel area.

The second align key 137 corresponds to the first align key 135 in the second direction. The second align key 137 provides the ink-jet device with the fourth piece of information. The fourth piece of information relates to a position of the pixel area having a center corresponding to the central portion 135e of the second align key 137 in the second direction.

For example, when the second align key 137 is “G5”, it indicates that a center of the green pixel area 142 corresponds to the central portion 135e of the second align key 137 in the second direction as shown in FIG. 2.

In addition, the fourth piece of information may enable the ink-jet device to find the position of the nozzle of the ink-jet device, the nozzle corresponding to the pixel area in which the jetting failure is generated. Thus, the ink-jet device may rearrange the nozzle to correspond to the center of the pixel area based on the first, second, third and the fourth pieces of information. Thus, the nozzle of the ink-jet device may precisely jet the colored ink toward the center of the pixel area so that the color filter pattern 140 may be formed efficiently without any jetting failure.

For example, in the event that the center of the colored ink drop positioned on the first align key 135 is separated from the central portion 135e in the first direction, the first set of graduations 135a may enable an interval between the center of the colored ink drop and the central portion 135e to be calculated as a numerical value.

The second align key 137 may provide the ink-jet device with the fourth piece of information G5 concerning the position of the green pixel area 142G that has its center corresponding to the central portion 135e of the first align key 135 in the fourth direction.

In addition, the fourth piece of information G5 may enable the ink-jet device to find the position of the nozzle of the ink-jet device, the nozzle generating the jetting failure in the green pixel area 142G.

The position of the nozzle may be rearranged on the basis of the first, the second, the third and/or the fourth piece of information. Thus, the nozzle may directly jet the colored ink toward the center of the green pixel area 142G. As a result, the jetting failure is hardly ever generated in the green pixel area 142G.

As illustrated in FIG. 2, the first align key 135 corresponds to the red pixel area 141R, the green pixel area 142G and the blue pixel area 143B that are adjacent to each other in the first direction. Alternatively, the first align key 135 may correspond to one of the red pixel area 141R, the green pixel area 142G and the blue pixel area 143B.

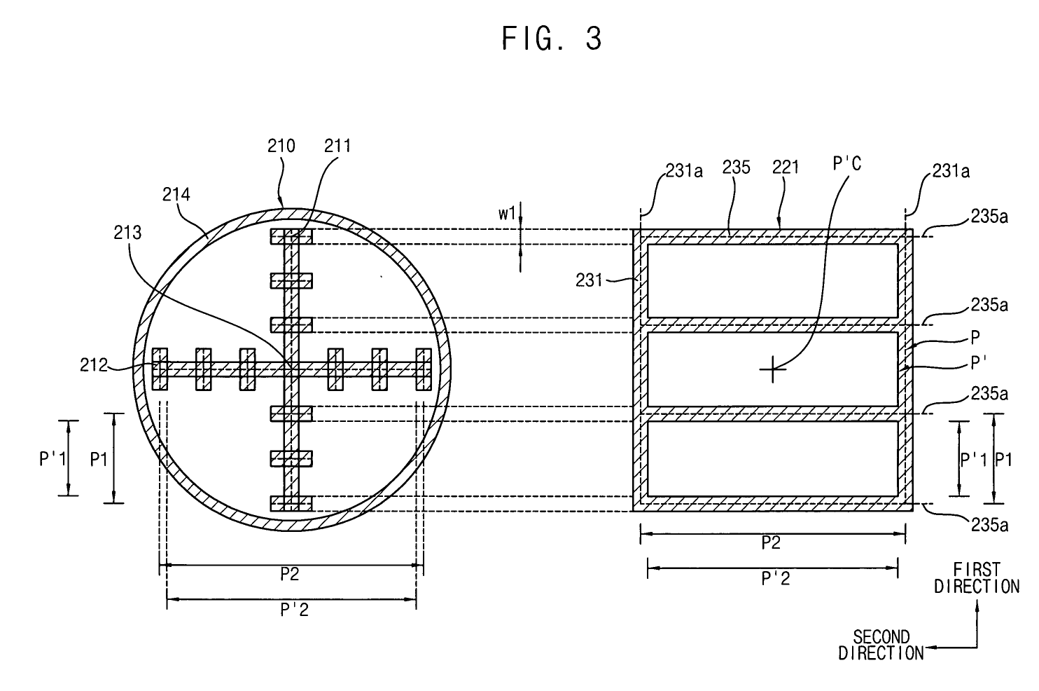

FIG. 3 is an enlarged view illustrating an example embodiment of the first align key in FIG. 2.

Referring to FIG. 3, the first align key 210 includes the first set of graduations 211 and the second set of graduations 212. The first set of graduations 211 are arranged in the first direction at first intervals. The second set of graduations 212 are arranged in the second direction at second intervals. The first interval is substantially identical to the second interval. The first align key 210 includes a central portion 213. The central portion 213 is used as the zero point of either the first set of graduations 211 or the second set of graduations 212. The light-blocking pattern 221 includes gate lines 231 and data lines 235. A width of the gate line 231 and a width of the data line 235 are substantially identical to each other. The width of the gate line 231 or the width of the data line 235 is hereinafter indicated as “W1”. The gate lines 231 are extended in the first direction in parallel with each other. The data lines 235 are extended in the second direction in parallel with each other. A first long side P2 and a first short side P1 together define a first pixel area P. The first long side P2 is substantially longer than the first short side P1. The first long side P2 is positioned between central axes 231a of the gate lines 231 that are adjacent to each other. The first short side P1 is positioned between central axes 235a of the data lines 235 that are adjacent to each other.

A second pixel area P′ is defined by the light blocking pattern 221. That is, the gate lines 231 that are adjacent to each other and the data lines 235 that are adjacent to each other together define a second pixel area P′. The second pixel area P′ has a second long side P′2 and a second short side P′1. The second long side P′2 is substantially longer than the second short side P′1.

A ratio of the first long side P2 to the first short side P1 is, for example, about 3:1. In addition, a ratio of the second long side P′2 to the second short side P′1 is also, for example, about 3:1.

A central portion 213 of the first align key 210 is separated from a central portion P° C. of the second pixel area P′ in the second direction.

A length between two of the first set of graduations 211 that have one graduation therebetween is substantially identical to a length of the second short side P′1. Therefore, the three successive ones of the first set of graduations 211 may divide the second short side P′1 into two equal parts.

A length between two of the second set of graduations 212 that have five successive graduations therebetween is substantially identical to a length of the second long side P′2 of the second pixel area P′. Therefore, seven successive ones of the second set of graduations 212 may divide the second long side P′2 of the second pixel area P′ into six equal parts.

Each first graduation 211 has a width substantially identical to that of the gate line 231. Each second graduation 212 has a width substantially identical to that of the data line 235. The width of each first graduation 211 is substantially identical to the width of each second graduation 212.

Referring again to FIG. 3, the first align key 210 includes a peripheral portion 214 surrounding the first set of graduations 211 and the second set of graduations 212. The peripheral portion 214 may have a circular shape.

As illustrated in FIG. 3, the first align key 210 corresponds to three pixel areas that are adjacent to each other. In an alternative embodiment, however, the first align key 210 may correspond to one pixel area or two pixel areas that are adjacent to each other. In other embodiments, the first align key 210 may correspond to four or more pixel areas that are adjacent to each other.

As illustrated in FIG. 3, the first align key 210 faces the first short side P1 and the second short side P′1. In other embodiments, the first align key 210 may face the first long side P2 and the second long side P′2.

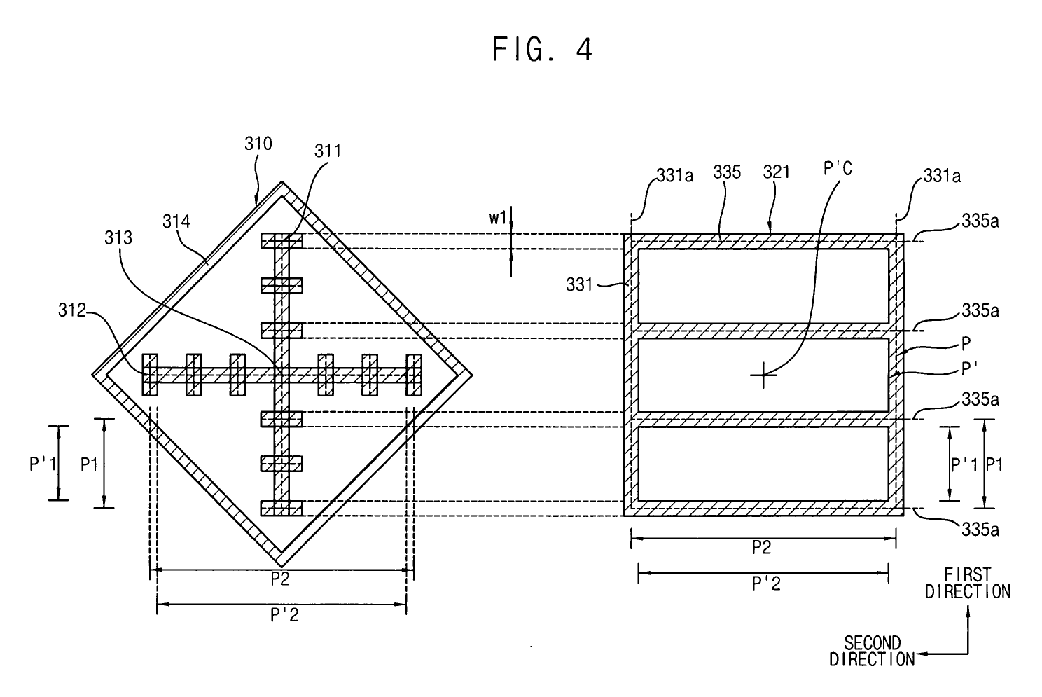

FIG. 4 is an enlarged view illustrating another example embodiment of a first align key in accordance with the present invention.

Referring to FIG. 4, the first align key 310 includes a first set of graduations 311 and a second set of graduations 312. The first set of graduations 311 are arranged in the first direction at first intervals. The second set of graduations 312 are arranged in the second direction at second intervals. The first interval is substantially identical to the second interval. The first align key 310 includes a central portion 313. The central portion 313 is used for either the first set of graduations 311 or the second set of graduations 312. The light-blocking pattern 321 includes gate lines 331 and data lines 335. A width of the gate line 331 and a width of the data line 335 are substantially identical to each other. The width of the gate line 331 or the width of the data line 335 is hereinafter indicated as “W1”. The gate lines 331 are extended in the first direction and are parallel with each other. The data lines 335 are extended in the second direction and are parallel with each other. A first long side P2 and a first short side P1 together define a first pixel area P. The first long side P2 is substantially longer than the first short side P1. The first long side P2 is positioned between central axes 331a of the gate lines 331 that are adjacent to each other. The first short side P1 is positioned between central axes 335a of the data lines 335 that are adjacent to each other.

A second pixel area P′ is defined by the light blocking pattern 321. That is, the gate lines 331 that are adjacent to each other and the data lines 335 that are adjacent to each other together define a second pixel area P′. The second pixel area P′ has a second long side P′2 and a second short side P′1. The second long side P′2 is substantially longer than the second short side P′1.

A ratio of the first long side P2 to the first short side P1 is, for example, about 3:1. In addition, a ratio of the second long side P′2 to the second short side P′1 is also, for example, about 3:1.

A central portion 313 of the first align key 310 is separated from a central portion P° C. of the second pixel area P′ in the second direction.

A length between two of the first set of graduations 311 that have one graduation therebetween is substantially identical to a length of the second short side P′1. Therefore, the three successive ones of the first set of graduations 311 may divide the second short side P′1 into two equal parts.

A length between two of the second set of graduations 312 that have five successive graduations therebetween is substantially identical to a length of the second long side P′2 of the second pixel area P′. Therefore, seven successive ones of the second set of graduations 312 may divide the second long side P′2 of the second pixel area P′ into six equal parts.

Each first graduation 311 has a width substantially identical to that of the gate line 331. Each second graduation 312 has a width substantially identical to that of the data line 335. The width of each first graduation 311 is substantially identical to the width of each second graduation 312.

Referring again to FIG. 4, the first align key 310 includes a peripheral portion 314 surrounding the first set of graduations 311 and the second set of graduations 312. The peripheral portion 314 may have a rectangular shape or a square shape.

As illustrated in FIG. 4, the first align key 310 corresponds to three successive pixel areas that are adjacent to each other. In one embodiment, the first align key 310 may correspond to a single pixel area. In another embodiment, the first align key 310 may correspond to two pixel areas that are adjacent to each other. In yet another embodiment, the first align key 310 may correspond to at least four or more pixel areas that are adjacent to each other.

As illustrated in FIG. 4, the first align key 310 faces with the first short side P1 and the second short side P′1. Alternatively, the first align key 310 may face the first long side P2 and the second long side P′2.

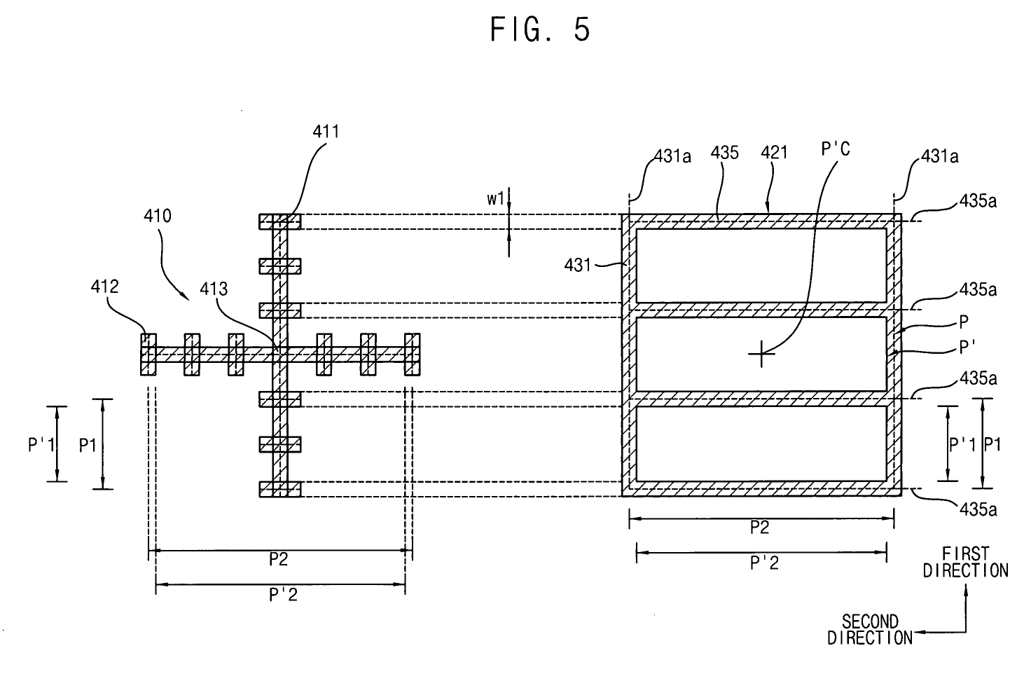

FIG. 5 is an enlarged view illustrating another example embodiment of the first align key in accordance with the present invention.

Referring to FIG. 5, the first align key 410 includes first set of graduations 411 and second set of graduations 412. The first set of graduations 411 are arranged in the first direction at first intervals. The second set of graduations 412 are arranged in the second direction at second intervals. The first interval is substantially identical to the second interval. The first align key 410 includes a central portion 413. The central portion 413 is used for either the first set of graduations 411 or the second set of graduations 412. The light-blocking pattern 421 includes gate lines 431 and data lines 435. A width of the gate line 431 and a width of the data line 435 are substantially identical to each other. The width of the gate line 431 or the width of the data line 435 is hereinafter indicated as “W1”. The gate lines 431 are extended in the first direction and are parallel with each other. The data lines 435 are extended in the second direction and are parallel with each other. A first long side P2 and a first short side P1 together define a first pixel area P. The first long side P2 is substantially longer than the first short side P1. The first long side P2 is positioned between central axes 431a of the gate lines 431 that are adjacent to each other. The first short side P1 is positioned between central axes 435a of the data lines 435 that are adjacent to each other.

A second pixel area P′ is defined by the light blocking pattern 421. That is, the gate lines 431 that are adjacent to each other and the data lines 435 that are adjacent to each other together define a second pixel area P′. The second pixel area P′ has a second long side P′2 and a second short side P′1. The second long side P′2 is substantially longer than the second short side P′1.

A ratio of the first long side P2 to the first short side P1 is for example, about 3:1. In addition, a ratio of the second long side P′2 to the second short side P′1 is also, for example about 3:1.

A central portion 413 of the first align key 410 is separated from a central portion P° C. of the second pixel area P′ in the second direction.

A length between two of the first set of graduations 411 that have one graduation therebetween is substantially identical to a length of the second short side P′1. Therefore, the three successive graduations of the first set of graduations 411 may divide the second short side P′1 into two equal parts.

A length between two of the second set of graduations 412 that have five successive graduations therebetween is substantially identical to a length of the second long side P′2 of the second pixel area P′. Therefore, seven successive graduations of the second set of graduations 412 may divide the second long side P′2 of the second pixel area P′ into six equal parts.

Each first graduation 411 has a width substantially identical to that of the gate line 431. Each second graduation 412 has a width substantially identical to that of the data line 435. The width of each first graduation 411 is substantially identical to the width of each second graduation 412.

Referring again to FIG. 5, the first set of graduations 411 and second set of graduations 412 directly face the light-blocking pattern 421. That is, the first align key 410 does not have a peripheral portion that encloses the first set of graduations 411 and second set of graduations 412.

As illustrated in FIG. 5, the first align key 410 corresponds to three pixel areas that are adjacent to each other. In one embodiment, the first align key 410 may correspond to a single pixel area. In another embodiment, the first align key 410 may correspond to two pixel areas that are adjacent to each other. Alternatively, the first align key 410 may correspond to four or more pixel areas that are adjacent to each other.

As illustrated in FIG. 5, the first align key 410 faces the first short side P1 and the second short side P′1. Alternatively, the first align key 410 may face the first long side P2 and the second long side P′2.

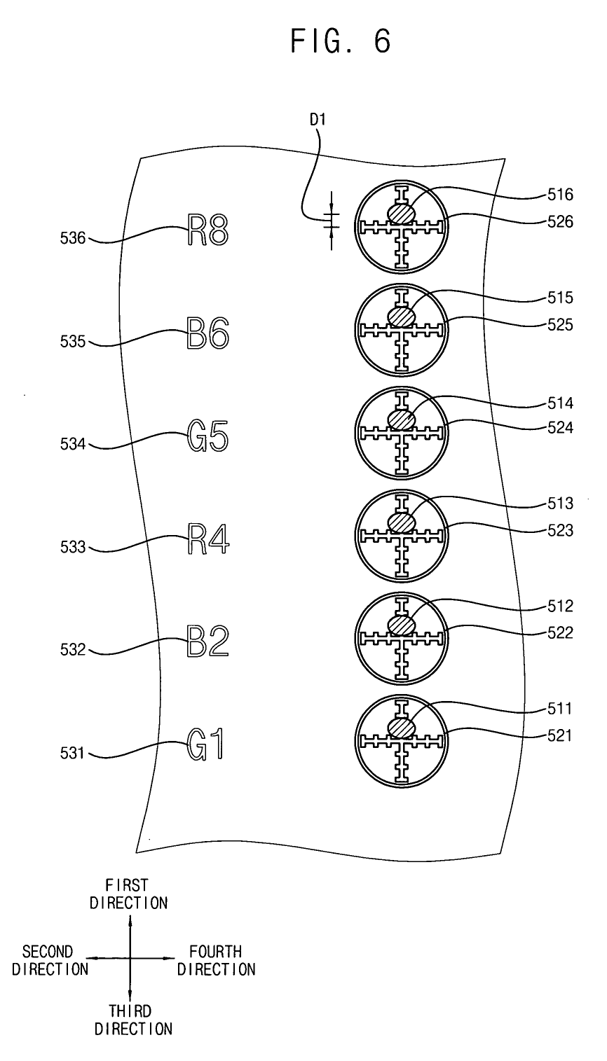

FIGS. 6 to 8 are plan views illustrating various types of the jetting failures detected by the color filter substrate of FIG. 1.

With reference now to the FIGS. 1 and 6, the light-blocking layer (not shown) is formed on a base substrate 110. The light-blocking layer is then patterned to form the light-blocking pattern 120 including the first light-blocking pattern 121, the second light-blocking pattern 123 and the third light-blocking pattern 130. The first light-blocking pattern 121 is formed on the display area DA. The second light-blocking pattern 123 is formed on the light-blocking area BA. The third light-blocking pattern 130 is formed on the peripheral area PA. The third light blocking pattern 130 includes first align keys 521 to 526 and second align keys 531 to 536.

The first light-blocking pattern 121 formed on the display area DA divides the display area DA into the pixel areas. The colored ink is jetted to each of the pixel areas by the ink-jet device. The colored ink may be red ink, green ink or blue ink In order to check whether or not the nozzle of the ink-jet device precisely corresponds to the center of the pixel area, the colored ink is jetted to the first align keys 521 to 526 that are formed on the peripheral area PA prior to jetting the colored ink to the pixel areas formed on the display area DA.

As described in FIG. 6, ink drops 511 to 516 may be separated from central portions of the first align keys 521 to 526 in the first direction by a first distance D1. This generally occurs because the nozzles of the ink-jet device are separated from the central portions of the first align keys 521 to 526 in the first direction by the first distance D1. In order for the colored ink drops 511 to 516 to be positioned at the central portions of the first align keys 521 to 526, the ink-jet device including the nozzles may be displaced in a third direction by the first distance D1. Alternatively, the base substrate 110 may be displaced in the first direction by the first distance D1. Thus, the colored ink drops 511 to 516 may be precisely positioned at the central portions of the first align keys 521 to 526.

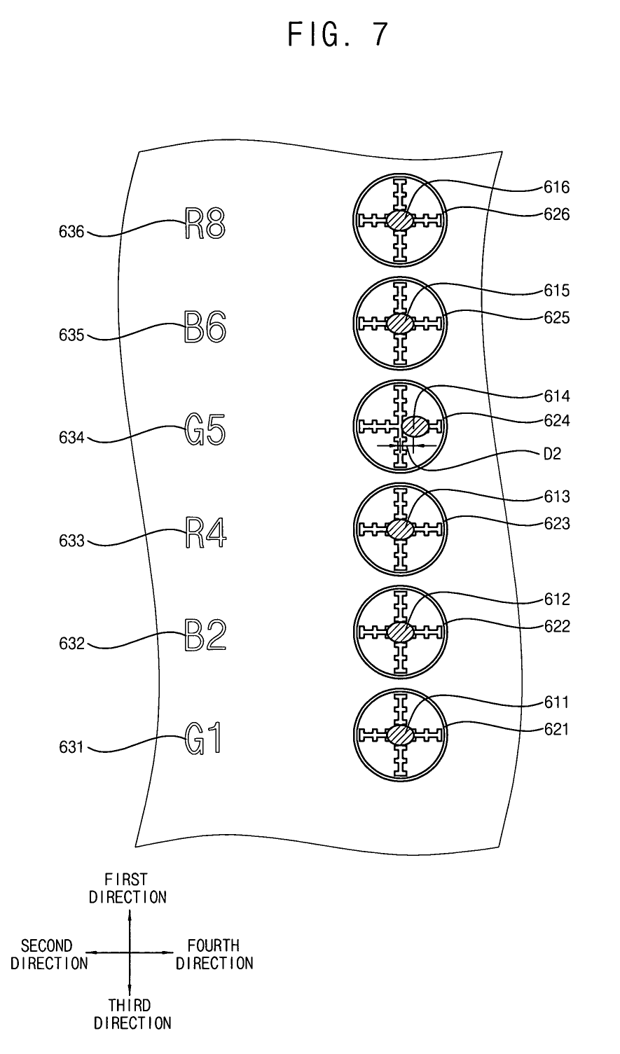

The colored ink is then jetted to the pixel areas formed on the display area DA, thereby suppressing a potential jetting failure. Referring to FIGS. 1 and 7, first align keys 621 to 626 and second align keys 631 to 636 are formed on the peripheral area PA of the base substrate 110.

In order to determine whether or not the nozzles of the ink-jet device precisely correspond to the pixel areas, the colored ink is jetted to the first align keys 621 to 626 that are formed on the peripheral area PA prior to jetting the colored ink to the pixel areas formed on the display area DA.

As described in FIG. 7, an ink drop 614 may be separated from a central portion of the first align key 624 in a fourth direction by a second distance D2. This occurs because the nozzles of the ink-jet device are separated from the central portions of the first align keys 621 to 626 in the fourth direction by the second distance D2. Thus, in order for the colored ink drops 611 to 616 to be positioned at the central portions of the first align keys 621 to 626, the ink-jet device including the nozzles may be displaced in a second direction by the second distance D2. Alternatively, the base substrate 110 may be displaced in the fourth direction by the 2, second distance D2. Thus, the colored ink drops 611 to 616 may be precisely positioned at the central portions of the first align keys 621 to 626.

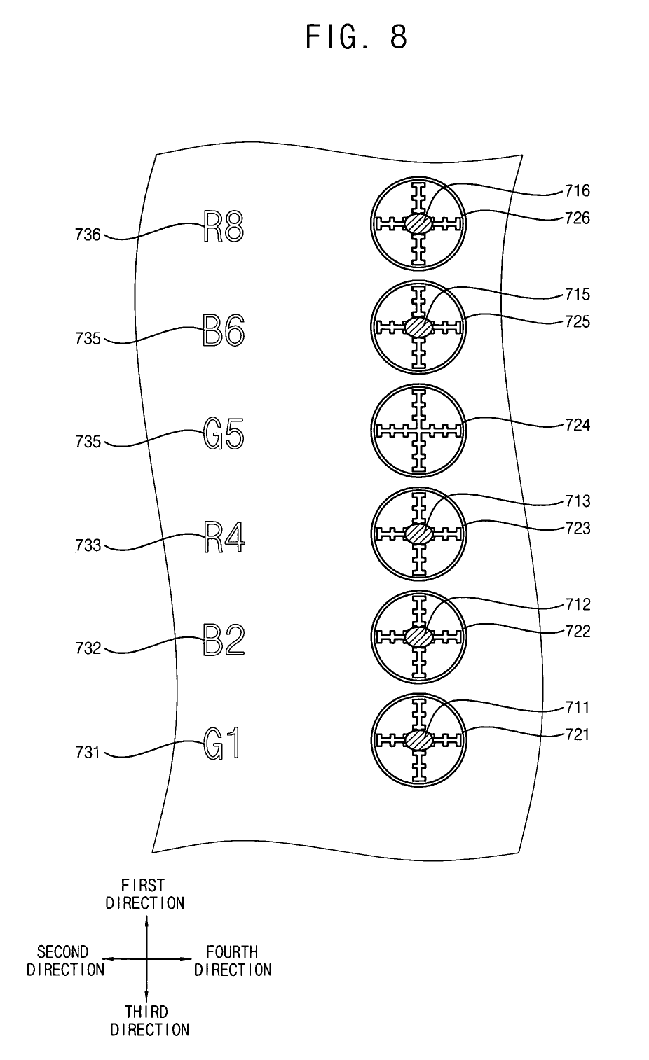

Referring to FIGS. 1 and 8, first align keys 721 to 726 and second align keys 731 to 736 are formed on the peripheral area PA of the base substrate 110.

In order to check whether or not nozzles of an ink-jet device precisely correspond to the pixel areas, the colored ink is jetted to the first align keys 721 to 726 that are formed on the peripheral area PA prior to jetting the colored ink to the pixel areas formed on the display area DA.

With reference to the FIG. 8, when there is no ink drop on the first align key 724, it is because the nozzle jetting the colored ink to the first align key 724 is clogged. The second align key 735 may explain the position of a pixel area corresponding to the nozzle that is clogged. Here, the first align key 724 corresponds to the second align key 735. The second align key 735 indicates a “G5”. The “G5” is the position of the pixel area corresponding to the nozzle that is clogged. Thus, the position of the nozzle that is clogged may be detected.

The nozzle that is clogged is then opened. Thus, the colored ink may be jetted from the nozzles to each of the pixel areas.

According to the present invention, a base substrate includes a display area and a peripheral area that encloses the display area. A light-blocking layer formed on the base substrate is patterned to form a first align key and a second align key on the peripheral area. The first align key provides an ink-jet device with an information concerning a jetting failure. The second align key provides the ink-jet device with an information concerning a position of a pixel area where the jetting failure is generated. Thus, the in-jet device may rearrange the base substrate and the ink-jet device so that the jetting failure may be efficiently suppressed.

The foregoing is illustrative of the present invention and is not to be construed as limiting thereof. Although a few example embodiments of this invention have been described, those skilled in the art will readily appreciate that many modifications are possible in the example embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed is:

1. A color filter substrate comprising:
a base substrate comprising a display area and a peripheral area, the peripheral area being disposed around the display area, the display area having pixel areas;
align portions formed on the peripheral area, each of the align portions corresponding to at least one pixel area, each align portion providing an information for arranging a nozzle of an ink-jetting device such that the nozzle jets a colored ink towards a center of each pixel area; and
a color filter portion formed on the base substrate by jetting the colored ink to the pixel areas.

2. The color filter substrate of claim 1, further comprising a first light-blocking pattern disposed between the pixel areas to define the respective pixel areas.

3. The color filter substrate of claim 2, further comprising a second light-blocking pattern disposed between the align portions and the color filter portion.

4. The color filter substrate of claim 2, wherein the align portions and the first light-blocking pattern are formed by patterning a light-blocking layer disposed on the base substrate.

5. The color filter substrate of claim 4, wherein the align portions comprise a protrusion.

6. The color filter substrate of claim 2, wherein the align portions comprise a recess.

7. The color filter substrate of claim 1, wherein the align portions include a first align key having a central portion with graduations arranged in a selected direction away from the central portion, wherein the central portion is positioned on an imaginary line passing through the centers of corresponding pixel areas, the first align key providing a first piece of information, a second piece of information and a third piece of information, the first piece of information concerning whether or not the colored ink is jetted from the nozzle of the ink-jet device to the pixel area, the second piece of information concerning how far a center of a colored ink drop jetted from the nozzle of the ink-jet device to a pixel area is separated from a center of the pixel area, the third piece of information concerning what direction the center of the colored ink drop jetted from the nozzle of the ink-jet device to the pixel area is separated from the center of the pixel area.

8. The color filter substrate of claim 7, wherein each pixel area comprises a long side, and a short side that is substantially shorter than the long side and the first align key comprises a first set of graduations and a second set of graduations, the first set of graduations dividing the long side into at least six equal parts and the second set of graduations dividing the short side into at least two equal parts.

9. The color filter substrate of claim 8, wherein the first and second set of graduations have a width substantially identical to an interval between two adjacent pixel areas.

10. The color filter substrate of claim 7, wherein the align portions comprise a second align key providing a fourth piece of information concerning a position of the pixel area.

11. The color filter substrate of claim 10, wherein the first align key is formed between the display area and the second align key.

12. The color filter substrate of claim 1, the color filter portion comprises a red filter pattern transmitting a ray of red light, a green filter pattern transmitting a ray of green light, a blue filter pattern transmitting a ray of blue light.

13. A color filter substrate comprising:
a base substrate comprising a display area, a first peripheral area and a second peripheral area, the display area having pixel areas, the first peripheral area and the second peripheral area enclosing the display area;
a first align key formed on the first peripheral area, the first align key having a central portion with graduations, the graduations being arranged in a selected direction away from the central portion, wherein the central portion is positioned on an imaginary line passing through centers of the pixel areas, the first align key providing a first piece of information, a second piece of information and a third piece of information, the first piece of information concerning whether or not a colored ink is jetted from a nozzle of an ink-jet device to a pixel area, the second piece of information concerning how far a center of a colored ink drop jetted from the nozzle of the ink-jet device to the pixel area is separated from the center of the pixel area, the third piece of information concerning to what direction the center of the colored ink drop jetted from the nozzle of the ink-jet device to the pixel area is separated from the center of the pixel area;
a second align key formed on the second peripheral area, the second align key providing a fourth piece of information concerning a position of the pixel area; and
a color filter portion formed on the base substrate by jetting the colored ink to the pixel areas.

14. The color filter substrate of claim 13, wherein the first align key is formed between the color filter portion and the second align key.

15. The color filter substrate of claim 13, further comprising a light blocking pattern defining the respective pixel areas, wherein the first and second align keys comprise a material substantially identical to that included in the light-blocking pattern.

16. A method for manufacturing a color filter substrate, the method comprising:
forming a light-blocking layer on a base substrate comprising a display area and a peripheral area that is positioned around the display area, the display area having a short side and a long side, wherein the long side is substantially longer than the short side; and
patterning the light-blocking layer to form a light-blocking pattern and align portions, the light-blocking pattern defining pixel areas on the display area, the align portions providing an information for arranging a nozzle of an ink-jetting device such that the nozzle jets a colored ink toward a center of each pixel area, the align portions including first align portions and second align portions, the first align portions arranged in a first direction substantially parallel with the long side of the display area, the second align portions arranged in a second direction in parallel with the short side of the display area.

17. The method of claim 16, further comprising arranging the nozzle such that the nozzle jets the colored ink toward a center of a selected pixel area based on the information.

18. The method of claim 17, wherein arranging the nozzle comprises arranging first nozzles arranged in the first direction by using the first align portions.

19. The method of claim 17, wherein arranging the nozzle comprises arranging second nozzles arranged in the second direction by using the second align portions.

20. The method of claim 16, further comprises forming a color filter pattern by jetting the colored ink to the pixel areas.

21. The method of claim 16, wherein the align portions include a first align key having a central portion with graduations arranged in a selected direction away from the central portion, wherein the central portion positioned on an imaginary line passing through the centers of corresponding pixel areas, the first align key providing a first piece of information, a second piece of information and a third piece of information, the first piece of information concerning whether or not the colored ink is jetted from the nozzle of the ink-jet device to a pixel area, the second piece of information concerning how far a center of a colored ink drop jetted from the nozzle of the ink-jet device to the pixel area is separated from a center of the pixel area, the third piece of information concerning to what direction the center of the colored ink drop jetted from the nozzle of the ink-jet device to the pixel area is separated from the center of the pixel area.

22. The color filter substrate of claim 21, wherein the align portions include a second align key providing a fourth piece of information concerning a position of the pixel area.

23. The color filter substrate of claim 22, wherein forming the align portions comprises forming the first align key between the display area and the second align key.
